(19) United States
(12) Patent Application Publication
(10) Pub. No.: US 2014/0000944 A1
(43) Pub. Date: Jan. 2, 2014

(54) TOUCH PANEL

(71) Applicant: PANASONIC CORPORATION, Osaka (JP)

(72) Inventors: Koji TANABE, Osaka (JP); Keishiro MURATA, Kyoto (JP)

(21) Appl. No.: 13/929,625

(22) Filed: Jun. 27, 2013

(30) Foreign Application Priority Data
Jul. 2, 2012 (JP) 2012-148246

(51) Int. Cl. H05K 1/02

(52) U.S. Cl. CPC H05K 1/0274
USPC 174/255

(57) ABSTRACT

The touch panel includes a light transmissive substrate, a first light transmissive conductive layer, and a second light transmissive conductive layer. The first conductive layer is provided on an upper surface of the substrate, and extending in a roughly band-shaped form in a first direction. The second conductive layer is provided on the upper surface of the substrate, insulated from the first conductive layer, and extending in a roughly band-shaped form in a second direction perpendicular to the first direction. The first conductive layers and the second conductive layers are plurally provided. The second conductive layer includes conductive parts provided on the upper surface of the substrate, and a connecting part provided for connecting the conductive parts in the second direction, and provided above the first conductive layer, and material of the connecting part is resin containing dispersed conductive fine wires.

### BACKGROUND

1. Technical Field

The present invention relates to a touch panel mainly used for operating various kinds of electronic devices.

2. Background Art

Recently, as various kinds of electronic devices such as a cellular phone or a digital still camera have become highly functional and more diversified, an increasing number of electronic devices are mounting light transmissive touch panels on front surfaces of display elements such as a liquid crystal display element. Users can switch various functions of the electronic device by touching and operating the touch panel with a finger or the like while seeing a display of the display element provided on a back surface through the touch panel. The touch panel used as described above is required to be easy to recognize the display element on the back surface, low in cost, and capable of performing reliable operations.

A conventional touch panel will be described with reference to FIG. 7.

In FIG. 7, dimensions are partially enlarged for easy understanding of a configuration.

FIG. 7 is an exploded perspective view of the conventional touch panel. Referring to FIG. 7, reference numeral 1 represents a film-shaped light transmissive upper substrate. A plurality of upper conductive layers 2 and a plurality of upper electrodes 3 are formed on an upper surface of upper substrate 1. Upper conductive layer 2 is made of light transmissive material such as indium tin oxide, and formed so as to extend in a roughly band-shaped form in a vertical direction. Upper electrode 3 is made of material such as silver or carbon, and provided in such a manner that one end of upper electrode 3 is connected to an end part of upper conductive layer 2, and the other end of upper electrode 3 is positioned at a peripheral right end of upper substrate 1. Upper electrode 3 is formed so as to extend in a horizontal direction perpendicular to upper conductive layer 2.

Reference numeral 4 represents a film-shaped light transmissive lower substrate which is similar to upper substrate 1. A plurality of lower conductive layers 5 and a plurality of lower electrodes 6 are formed on an upper surface of lower substrate 4. Lower conductive layer 5 is made of light transmissive material such as indium tin oxide, and formed so as to extend in a roughly band-shaped form in the horizontal direction perpendicular to upper conductive layer 2. Lower electrode 6 is made of material such as silver or carbon, and provided in such a manner that one end of lower electrode 6 is connected to an end part of lower conductive layer 5, and the other end of lower electrode 6 is positioned at a peripheral right end of lower substrate 4. Lower electrode 6 is formed so as to extend in the horizontal direction parallel to lower conductive layer 5.

Reference numeral 7 represents a plate-shaped or film-shaped light transmissive cover substrate. The touch panel is configured in such a manner that upper substrate 1 is overlapped on the upper surface of lower substrate 4, cover substrate 7 is overlapped on the upper surface of upper substrate 1, and these are bonded respectively with a bonding agent (not shown) or the like.

The touch panel thus configured is disposed on a front surface of a display element such as a liquid crystal display element and mounted on the electronic device. Upper electrodes 3 and lower electrodes 6 provided so as to extend at the peripheral right ends of the touch panel are electrically connected to an electronic circuit (not shown) of the electronic device, through a flexible wiring board, a connector (not shown), or the like.

In the above configuration, while a voltage is sequentially applied to upper electrodes 3 and lower electrodes 6 from the electronic circuit, an upper surface of cover substrate 7 is touched and operated with a finger or the like, according to a display of the display element provided on a back surface of the touch panel. Thus, electrostatic capacity between upper conductive layer 2 and lower conductive layer 5 positioned at the operated part is changed, and the electronic circuit detects the operated position, so that various functions of the electronic device can be switched.

For example, under a condition that a plurality of menus are displayed on the display element on the back surface, the upper surface of cover substrate 7 positioned above a desired menu is touched with a finger or the like. Electric charge is partially conducted to this finger, and the capacity between upper conductive layer 2 and lower conductive layer 5 is changed at the operated part of the touch panel. When the electronic circuit detects the change in capacity, the desired menu can be selected.

As conventional art document information related to the present invention of this application, Unexamined Japanese Patent Publication No. 2009-93397 is known, for example.

### SUMMARY

However, according to the conventional touch panel, upper substrate 1 having upper conductive layers 2 formed on the upper surface and lower substrate 4 having lower conductive layers 5 formed on the upper surface are overlapped and attached on a lower surface of cover substrate 7. Therefore, the touch panel is large in thickness as a whole, and has many components, and its cost is high.

The present application provides a touch panel which is reduced in number of components, low in cost, and capable of performing reliable operations.

A touch panel according to the present invention includes a light transmissive substrate, a first light transmissive conductive layer, and a second light transmissive conductive layer. The first conductive layer is provided on an upper surface of the substrate, and extending in a roughly band-shaped form in a first direction. The second conductive layer is provided on the upper surface of the substrate, insulated from the first conductive layer, and extending in a roughly band-shaped form in a second direction perpendicular to the first direction. The first conductive layers and the second conductive layers are plurally provided. The second conductive layer includes a plurality of conductive parts provided on the upper surface of the substrate, and a connecting part provided for connecting the conductive parts in the second direction, and provided above the first conductive layer, and material of the connecting part is resin containing dispersed conductive fine wires.

Since the first conductive layers and the second conductive layers are provided on the upper surface of the one substrate, the number of components is small, and assembling can be easily performed. In addition, the conductive parts can be surely connected by the connecting part.

As described above, the present invention can provide the touch panel which has a small number of components, is low in cost, and capable of performing reliable operations.

### BRIEF DESCRIPTION OF DRAWINGS

FIG. 1 is a cross-sectional view of a touch panel according to the present exemplary embodiment;

FIG. 2 is a plan view of the touch panel according to the present exemplary embodiment;

FIG. 3A is a partial cross-sectional view showing a step of manufacturing the touch panel according to the present exemplary embodiment;

FIG. 3B is a partial cross-sectional view showing a step of manufacturing the touch panel according to the present exemplary embodiment;

FIG. 3C is a partial cross-sectional view showing a step of manufacturing the touch panel according to the present exemplary embodiment;

FIG. 3D is a partial cross-sectional view showing a step of manufacturing the touch panel according to the present exemplary embodiment;

FIG. 4A is a partial cross-sectional view showing a step of manufacturing the touch panel according to the present exemplary embodiment;

FIG. 4B is a partial cross-sectional view showing a step of manufacturing the touch panel according to the present exemplary embodiment;

FIG. 4C is a partial cross-sectional view showing a step of manufacturing the touch panel according to the present exemplary embodiment;

FIG. 5A is a partial plan view showing a step of manufacturing the touch panel according to the present exemplary embodiment;

FIG. 5B is a partial plan view showing a step of manufacturing the touch panel according to the present exemplary embodiment;

FIG. 5C is a partial plan view showing a step of manufacturing the touch panel according to the present exemplary embodiment;

FIG. 5D is a partial plan view showing a step of manufacturing the touch panel according to the present exemplary embodiment;

FIG. 6 is a partial cross-sectional view of a touch panel according to a variation of the present exemplary embodiment; and

FIG. 7 is an exploded perspective view of a conventional touch panel.

### DETAILED DESCRIPTION OF THE PREFERRED EMBODIMENT

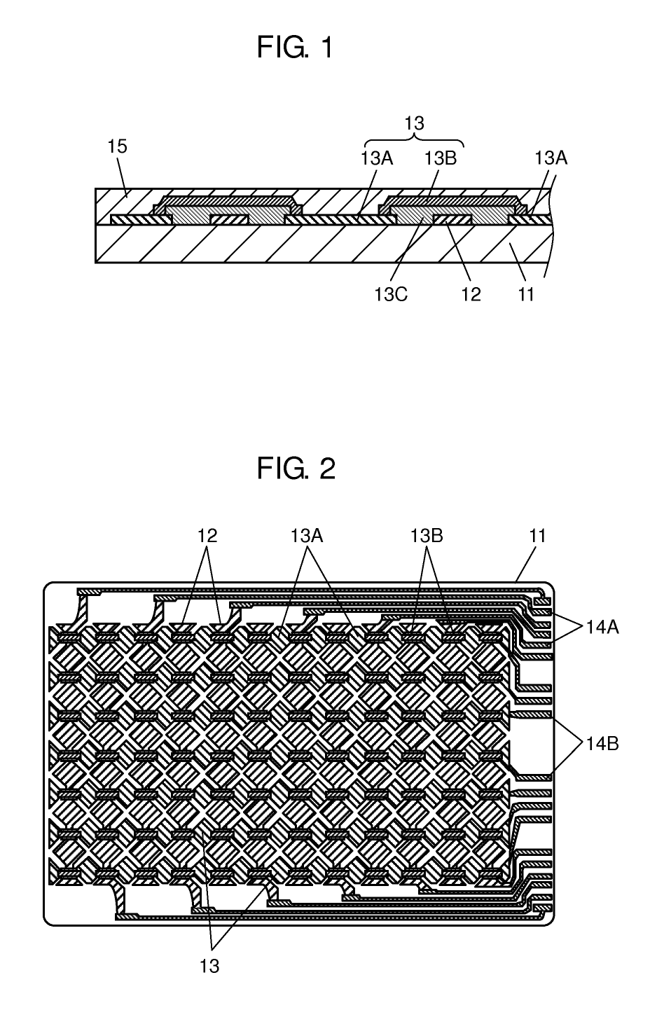

Hereinafter, an exemplary embodiment of the present invention will be described with reference to FIGS. 1 to 6.

In these drawings, dimensions are partially enlarged for easy understanding of a configuration.

### Exemplary Embodiment

FIG. 1 is a cross-sectional view of a touch panel according to the present exemplary embodiment, and FIG. 2 is a plan view of the touch panel according to the present exemplary embodiment. Referring to FIGS. 1 and 2, reference numeral 11 represents a film-shaped light transmissive substrate made of material such as polyethylene terephthalate, polyether sulfone, or polycarbonate. A plurality of first conductive layers 12 are formed on an upper surface of substrate 11. First conductive layer 12 is made of light transmissive material such as indium tin oxide or tin oxide, and formed so as to extend in a roughly band-shaped form in a vertical direction. The vertical direction is assumed to be a first direction.

First conductive layer 12 is formed in such a manner that a plurality of square parts are connected in a roughly band-shaped form. In addition, a plurality of roughly square-shaped void parts are provided between adjacent first conductive layers 12, and a plurality of roughly rectangle-shaped conductive parts 13A made of light transmissive material such as indium tin oxide or tin oxide are formed in the void parts. Roughly rectangle-shaped conductive parts 13A are not connected but separated from each other. According to the present exemplary embodiment, first conductive layers 12 and conductive parts 13A are formed at the same time, so that they are made of the same material and have the same film thickness. As a result, it becomes possible to simplify steps. However, first conductive layer 12 and conductive part 13A may be formed separately from each other, so that they are made of different materials and have different film thicknesses. As a result, each of them can be made of optimal material and has an optimal thickness.

The plurality of conductive parts 13A are connected by a plurality of light transmissive connecting parts 13B in a horizontal direction perpendicular to first conductive layer 12, and thus a plurality of second light transmissive conductive layers are provided in a roughly band-shaped form. The horizontal direction is assumed to be a second direction. Connecting part 13B is formed in such a manner that a plurality of conductive fine wires made of material such as silver, copper, or carbon are dispersed in light transmissive ultraviolet curable resin made of material such as acrylate or methacrylate. The conductive fine wire has a diameter ranging from 10 nm to 300 nm, and a length ranging from 1 nm to 100 nm. Second conductive layers 13 and first conductive layers 12 are formed on the upper surface of substrate 11 with predetermined spaces between them.

Light transmissive insulating layer 13C made of resin material such as acrylate or methacrylate is formed between connecting part 13B and first conductive layer 12 by a method such as printing or exposing/developing. First conductive layer 12 and second conductive layer 13 are insulated from each other by insulating layer 13C.

In addition, light transmissive insulating layer 13C may be made of ultraviolet curable resin material such as acrylate or methacrylate.

In addition, in a case where connecting part 13B and insulating layer 13C are made of the same resin material, reflection can be minimized at an overlapping interface, and transmittance as the touch panel can be improved, so that a display element on a back surface can be easily recognized.

Reference numerals 14A and 14B represent a first electrode and a second electrode, respectively made of silver or carbon by printing, or made of copper foil by vapor deposition. One end of first electrode 14A is connected to an end part of first conductive layer 12, and one end of second electrode 14B is connected to an end part of second conductive layer 13. First electrode 14A and second electrode 14B are formed so as to extend in the horizontal direction in such a manner that the other end of first electrode 14A and the other end of second electrode 14B are positioned at a peripheral right end of substrate 11.

Reference numeral 15 represents a cover layer made of material such as acryl, polycarbonate, or epoxy. Cover layer 15 is formed on the upper surface of substrate 11 by printing or the like in such a manner that cover layer 15 covers the whole upper surface of substrate 11 except for the peripheral right end, and thus the touch panel is provided.

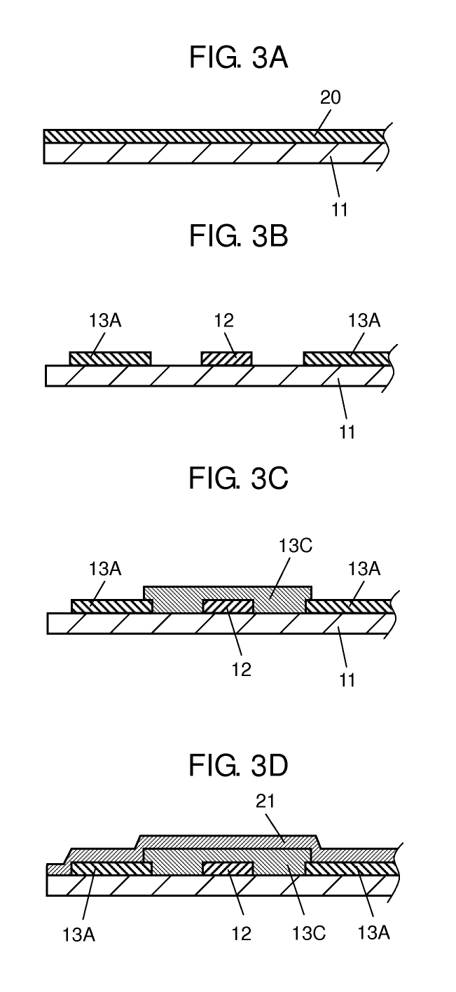

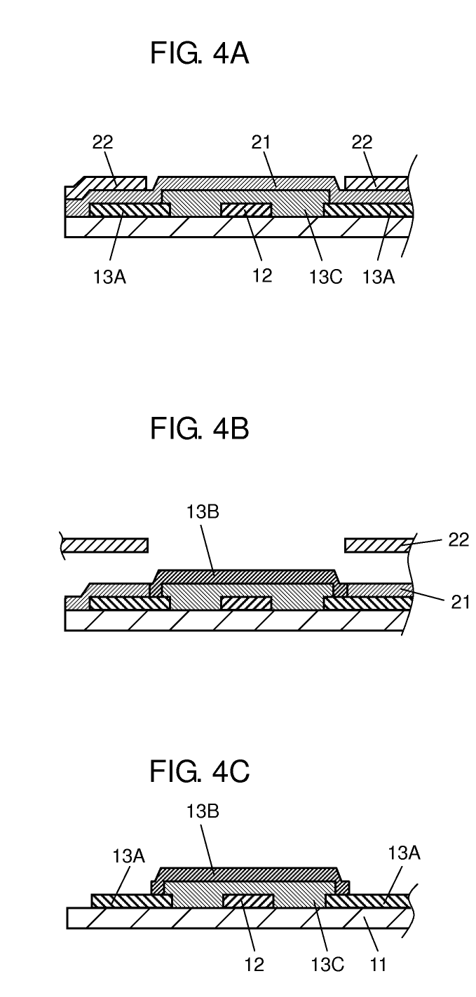

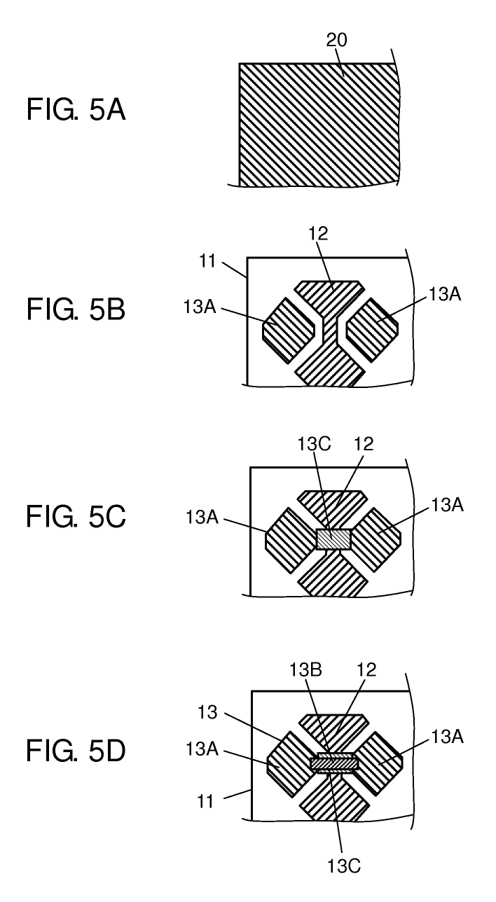

Next, a method for manufacturing the above touch panel will be described with reference to FIGS. 3A to 5D. FIGS. 3A to 4C are partial cross-sectional views showing steps for manufacturing the touch panel according to the present exemplary embodiment. FIGS. 5A to 5D are partial plan views showing the steps for manufacturing the touch panel according to the present exemplary embodiment.

As shown in FIGS. 3A and 5A, conductive thin film 20 made of material such as indium tin oxide is formed on a whole surface of the upper surface of substrate 11.

Then, an upper surface of conductive thin film 20 is covered with a film made of insulating resin such as dry film resist which has been formed so as to have patterns of first conductive layers 12 and conductive parts 13A. Then, conductive thin film 20 is soaked in a predetermined etching solution, and conductive thin film 20 positioned at unnecessary parts is removed with the patterned insulating resin film used as a mask. Thus, as shown in FIGS. 3B and 5B, first conductive layers 12 and conductive parts 13A are formed on the upper surface of substrate 11.

Then, as shown in FIGS. 3C and 5C, light transmissive insulating layer 13C is formed between conductive parts 13A so as to cover first conductive layer 12 by a method such as printing or exposing/developing.

Then, as shown in FIG. 3D, ultraviolet curable resin 21 in which the plurality of conductive fine wires are dispersed is formed on substrate 11, first conductive layer 12, conductive parts 13A, and insulating layer 13C. In this case, heights of upper surfaces of ultraviolet curable resin 21 reflect heights of substrate 11, first conductive layer 12, conductive parts 13A, and insulating layer 13C which all serve as base members. More specifically, the height of the upper surface of ultraviolet curable resin 21 is highest at an upper part of insulating layer 13C, and it is second highest at an upper part of first conductive layer 12 (not shown) and conductive parts 13A which are not covered with insulating layer 13C. In addition, the height of the upper surface of ultraviolet curable resin 21 is lowest at a part which is formed to be in contact with substrate 11.

Then, as shown in FIG. 4A, film 22 having an opening in which connecting part 13B will be provided is formed.

Then, as shown in FIG. 4B, ultraviolet curable resin 21 is irradiated with ultraviolet light, and exposed ultraviolet curable resin 21 in the opening of film 22 is completely cured. At this time, when insulating layer 13C positioned under the opening of film 22 is made of ultraviolet curable resin, it can be completely cured at the same time. In addition, in order to electrically connect conductive parts 13A positioned adjacently, in view of precision of a process, a length of the opening of film 22 is longer than a length of insulating layer 13C in the horizontal direction of substrate 11. In addition, in order to avoid being connected to first conductive layer 12 which is not covered with insulating film 13C to keep the insularity property, in view of precision of a process, a length of the opening of film 22 is shorter than a length of insulating layer 13C in the vertical direction of substrate 11. The lengths of the opening of film 22 serve as lengths of connecting part 13B which will be formed later. Then, film 22 is removed from the upper surface of ultraviolet curable resin 21.

Then, as shown in FIGS. 4C and 5D, ultraviolet curable resin 21 which has not been cured because it was covered with film 22 is removed, and thus connecting parts 13B are formed. As a result, conductive parts 13A are connected by connecting parts 13B in the horizontal direction perpendicular to first conductive layer 12, and thus roughly band-shaped second conductive layers 13 are formed.

In addition, cover layer 15 is formed on the upper surface of substrate 11 by printing or the like so as to cover the whole surface except for the peripheral right end, so that the touch panel shown in FIG. 1 is completed.

In addition, when connecting part 13B is made of ultraviolet curable resin 21 as described above, a curing operation can be performed in a short time, which is preferable, but it may be made of resin other than ultraviolet curable resin 21, such as heat curable resin, according to a holding facility. Also, a light transmissive electron beam curable resin made of material such as acrylate or methacrylate can be used instead of ultraviolet curable resin 21. In case of using electron beam curable resin, an electron beam is used in exposing/developing method.

The touch panel thus configured is disposed on a front surface of a display element such as a liquid crystal display element, and thus mounted on an electronic device. First electrodes 14A and second electrodes 14B provided so as to extend at the peripheral right end of the touch panel are electrically connected to an electronic circuit (not shown) of the electronic device, through a flexible wiring plate or a connector (not shown).

In the above configuration, while a voltage is sequentially applied to first electrodes 14A and second electrodes 14B from the electronic circuit, an upper surface of cover layer 15 is touched and operated with a finger or the like, according to a display of the display element provided on a back surface of the touch panel. Thus, electrostatic capacity between first conductive layer 12 and second conductive layer 13 positioned at the operated part is changed, and the electronic circuit detects the operated part, so that various functions can be switched in the electronic device.

For example, under a condition that a plurality of menus are displayed on the display element on the back surface, the upper surface of cover layer 15 positioned above a desired menu is touched with a finger or the like. Electric charge is partially conducted to this finger, and capacity between first conductive layer 12 and second conductive layer 13 is changed at the operated part of the touch panel. When the electronic circuit detects the change in capacity, the desired menu can be selected.

Thus, according to the present exemplary embodiment, roughly band-shaped first conductive layers 12 and roughly band-shaped second conductive layers 13 extending in the direction perpendicular to first conductive layers 12 are disposed on the upper surface of one substrate 11 with the predetermined spaces provided between them. In this case, there is no need to use a plurality of substrates, the number of components can be reduced, and there is no need to overlap and attach the plurality of substrates to each other. In addition, each component possibly absorbs 0.5% to 20% of light, and generates interlayer interface reflection, so that when the number of the components is reduced, transmittance of the touch panel is improved. As a result, according to the touch panel thus formed, the display element on the back surface can be easily recognized, assembling is easy, and the cost is low.

As for second conductive layer 13, roughly rectangle-shaped conductive parts 13A are connected by connecting parts 13B made of ultraviolet curable resin in which the conductive fine wires are dispersed. Second conductive layer 13 is formed so as to extend in the direction perpendicular to first conductive layer 12. As a result, second conductive layer 13 can be formed at low cost by a simple method, and conductive parts 13A can be surely connected.

More specifically, compared with a case where connecting part 13B is formed of material such as indium tin oxide by sputtering or the like, connecting parts 13B can be formed by the simple method in which ultraviolet curable resin 21 is applied and cured on substrate 11, without needing facilities such as a vacuum device. Thus, conductive parts 13A can be surely connected by the conductive fine wires dispersed in connecting part 13B.

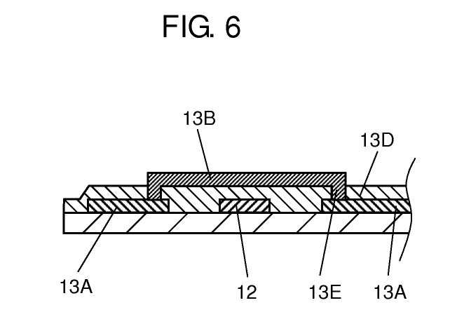

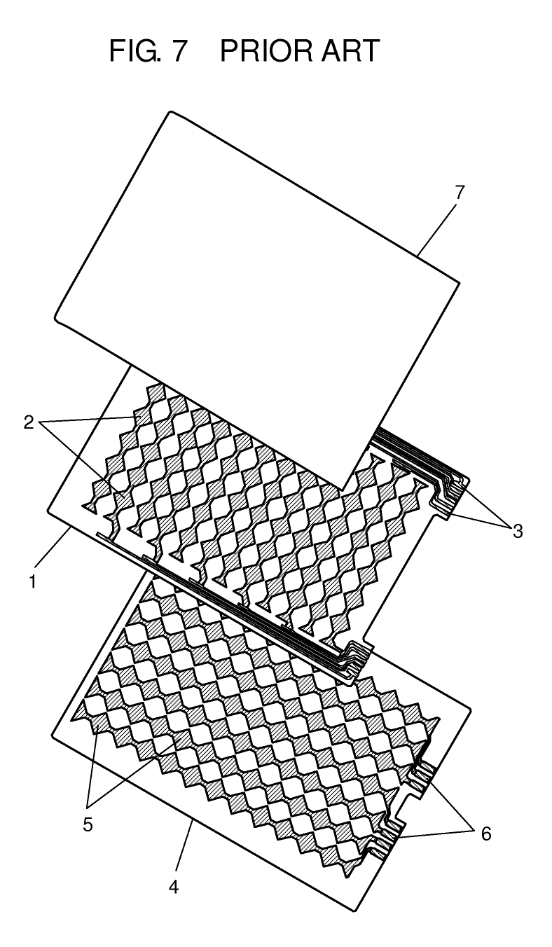

In addition, the above description has been given of the configuration in which insulating layer 13C is formed between conductive parts 13A so as to cover first conductive layer 12. FIG. 6 is a partial cross-sectional view of a touch panel according to a variation of the present exemplary embodiment. As shown in FIG. 6, according to the variation of the present exemplary embodiment, light transmissive insulating layer 13D is provided so as to cover the whole upper surface of substrate 11. Thus, via holes 13E are formed in insulating layer 13D, and connecting part 13B for connecting conductive parts 13A through via holes 13E is formed.

In addition, according to the present exemplary embodiment, second conductive layer 13 is composed of conductive parts 13A and connecting parts 13B for connecting conductive parts 13A. Instead of this, second conductive layer 13 may be formed into a roughly band-shaped form in which square parts are connected, and first conductive layer 12 may be formed in such a manner that conductive parts are connected by connecting parts. That is, first conductive layer 12 and second conductive layer 13 may be replaced with each other.

According to the present exemplary embodiment, first conductive layer 12 and conductive part 13A of second conductive layer 13 are made of the material such as indium tin oxide or tin oxide by sputtering or the like. Instead of this, material of first conductive layer 12 and conductive part 13A of second conductive layer 13 may be one having silver fine wires scattered in light transmissive acrylic resin, or light transmissive conductive resin material such as polythiophene or polyaniline.

According to the present exemplary embodiment, first conductive layer 12 is formed such that the square parts are connected, but instead of this, circular, ellipsoidal, polygonal, or rounded roughly polygonal parts may be connected. According to the present exemplary embodiment, conductive part 13A is in the roughly rectangular form, but instead of this, it may be in a circular, ellipsoidal, polygonal, or rounded roughly polygonal form.

In above description according to the embodiment, terms, such as “upper surface”, “lower surface”, and “above”, indicating directions merely indicate relative directions depending on the relative positional relationship of components, such as the substrate, the conductive layer, and the insulating layer, of the touch panel, and do not indicate absolute directions, such as a vertical direction.

Thus, according to the present exemplary embodiment, first conductive layers 12 having the roughly band-shaped form, and second conductive layers 13 extending in the roughly band-shaped form in the direction perpendicular to first conductive layers 12 are formed on the upper surface of substrate 11 with the predetermined spaces provided between them. Either first conductive layer 12 or second conductive layer 13 is composed of roughly rectangle-shaped conductive parts 13A, and connecting parts 13B made of ultraviolet curable resin in which the conductive fine wires are dispersed to connect conductive parts 13A. Thus, since first conductive layers 12 and second conductive layers 13 are formed on the upper surface of one substrate 11, the number of the components can be small, and the assembling can be easily performed. Furthermore, the touch panel in which conductive parts 13A can be surely connected by connecting parts 13B, and the reliable operation can be performed can be provided at low cost.

The touch panel according to the present invention has an advantageous effect of reducing the number of the components and ensuring low cost and reliable operations, and is useful for mainly operating various kinds of electronic devices.

What is claimed is:

1. A touch panel comprising:
a light transmissive substrate;
a first light transmissive conductive layer provided on an upper surface of the substrate, and extending in a roughly band-shaped form in a first direction; and
a second light transmissive conductive layer provided on the upper surface of the light transmissive substrate, insulated from the first light transmissive conductive layer, and extending in a roughly band-shaped form in a second direction perpendicular to the first direction, wherein
the first light transmissive conductive layer and the second light transmissive conductive layer are plurally provided, and
the second light transmissive conductive layer includes a plurality of conductive parts provided on the upper surface of the light transmissive substrate, and a connecting part provided for connecting the plurality of conductive parts in the second direction, and provided above the first light transmissive conductive layer, and material of the connecting part is resin containing dispersed conductive fine wires.

2. The touch panel according to claim 1, wherein
the first light transmissive conductive layer and the plurality of conductive parts are made of the same material and have the same film thickness.

3. The touch panel according to claim 1, wherein
an insulating layer is provided between the first light transmissive conductive layer and the connecting part.

4. The touch panel according to claim 3, wherein
a length of the connecting part in the first direction is shorter than a length of the insulating layer in the first direction.

5. The touch panel according to claim 3, wherein
a length of the connecting part in the second direction is longer than a length of the insulating layer in the second direction.

6. The touch panel according to claim 3, wherein
the insulating layer is provided on an upper surface of the plurality of conductive parts, and
the connecting part is connected to each of the plurality of conductive parts through an opening provided in the insulating layer.

7. The touch panel according to claim 3, wherein
the connecting part and the insulating layer are made of the same resin material.
